(19) United States
(12) Patent Application Publication
(10) Pub. No.: US 2026/0221204 A1
(43) Pub. Date: Jul. 30, 2026

(54) SEMICONDUCTOR STORAGE DEVICE

(71) Applicant: Kioxia Corporation, Tokyo (JP)

(72) Inventors: Ryota SHIMADA, Yokohama Kanagawa (JP); Shinji SUZUKI, Sagamihara Kanagawa (JP); Akiyuki MURAYAMA, Koto Tokyo (JP); Yasuhiro SHIINO, Fujisawa Kanagawa (JP); Tsuyoshi OGIKUBO, Yokohama Kanagawa (JP)

(73) Assignee: Kioxia Corporation, Tokyo (JP)

(21) Appl. No.: 19/272,973

(22) Filed: Jul. 17, 2025

(30) Foreign Application Priority Data
Jan. 28, 2025 (JP) 2025-012370

(51) Int. Cl. G11C 16/34; G11C 7/10; G11C 8/12; G11C 16/04

(52) U.S. Cl. CPC G11C 16/3445; G11C 7/1096; G11C 8/12; G11C 16/0483

(57) ABSTRACT

In one embodiment, a semiconductor storage device includes a first string including plural memory cells and first and second select transistors. The plural memory cells in the first string include plural first memory cells in a first sub-block adjacent to the first select transistor, plural second memory cells in a second sub-block adjacent to the second select transistor, and a first intermediate cell between the first and second sub-blocks. When a write operation is performed in which the first sub-block is set as a selected sub-block, the second sub-block is set as a non-selected sub-block, the first string is set as a non-selected string, and a second string different from the first string is set as a selected string, a first precharge on the first string is performed in a state where the first intermediate cell is turned off, and the first and second select transistors are turned on.

### CROSS REFERENCE TO RELATED APPLICATION

This application is based upon and claims the benefit of priority from the prior Japanese Patent Application No. 2025-012370, filed on Jan. 28, 2025, the entire contents of which are incorporated herein by reference.

### FIELD

Embodiments described herein relate to a semiconductor storage device.

### BACKGROUND

In a semiconductor storage device such as a three-dimensional semiconductor memory, when a write operation or an erase operation on data is performed in a sub-block mode, there is a problem of, for example, charges that remain in a memory string.

### BRIEF DESCRIPTION OF THE DRAWINGS

FIG. 1 is a block diagram illustrating a configuration of a memory system of a first embodiment;

FIG. 2 is a circuit diagram illustrating a configuration of a memory cell array 1 of the first embodiment;

FIGS. 3A to 3C are diagrams for illustrating a write operation of the first embodiment;

FIG. 4 is a diagram for illustrating a precharge of the first embodiment;

FIGS. 5A and 5B are diagrams for illustrating a sub-block mode of the first embodiment;

FIGS. 6A and 6B are diagrams for illustrating an erase operation of the first embodiment;

FIGS. 7A and 7B are diagrams for illustrating the write operation of the first embodiment;

FIG. 8 is a diagram for illustrating a problem of the precharge of the first embodiment;

FIG. 9 is another diagram for illustrating the problem of the precharge of the first embodiment;

FIG. 10 is another diagram for illustrating the problem of the precharge of the first embodiment;

FIG. 11 is a diagram for illustrating an operation of the memory cell array 1 of the first embodiment;

FIG. 12 is another diagram for illustrating the operation of the memory cell array 1 of the first embodiment;

FIG. 13 is a diagram for illustrating an operation of the memory cell array 1 of a first modification of the first embodiment;

FIGS. 14A and 14B are diagrams for illustrating an operation of the memory cell array 1 of a second modification of the first embodiment;

FIGS. 15A to 15C are diagrams for illustrating a read operation of a second embodiment;

FIG. 16 is a flowchart for illustrating the erase operation of the second embodiment;

FIG. 17 is a graph for illustrating an erase verify operation of the second embodiment;

FIGS. 18A and 18B are diagrams for illustrating the erase verify operation of the second embodiment;

FIG. 19 is another diagram for illustrating the erase verify operation of the second embodiment;

FIG. 20 is a diagram for illustrating a problem of the erase verify operation of the second embodiment;

FIG. 21 is another diagram for illustrating the problem of the erase verify operation of the second embodiment;

FIG. 22 is a diagram for illustrating an operation of a memory cell array 1 of the second embodiment;

FIG. 23 is a graph for illustrating the operation of the memory cell array 1 of the second embodiment;

FIG. 24 is a diagram for illustrating an operation of the memory cell array 1 of a first modification of the second embodiment;

FIGS. 25A and 25B are diagrams for illustrating an operation of the memory cell array 1 of a second modification of the second embodiment; and

FIGS. 26A and 26B are diagrams for illustrating an operation of the memory cell array 1 of a third modification of the second embodiment.

### DETAILED DESCRIPTION

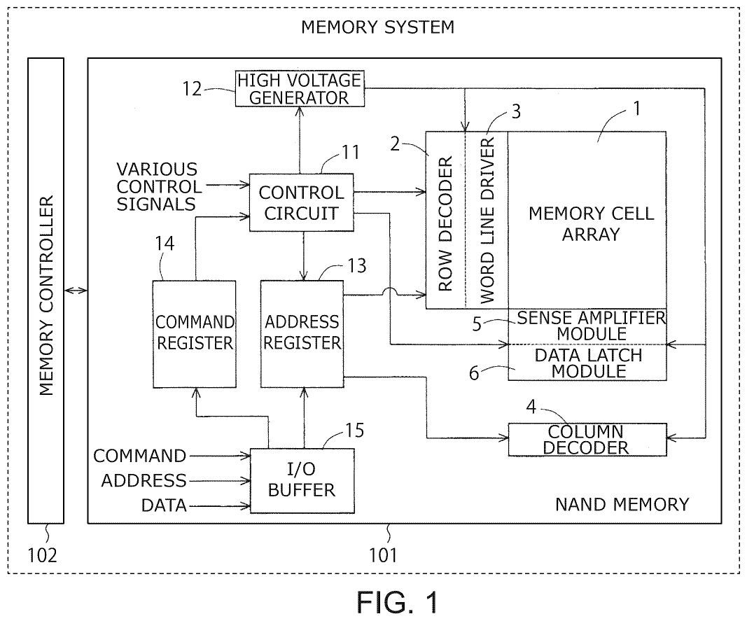

Embodiments will now be explained with reference to the accompanying drawings. In FIGS. 1 to 26B, same components are denoted by the same reference numerals, and will not be described repeatedly.

In one embodiment, a semiconductor storage device includes a first string including a plurality of memory cells, a first select transistor, and a second select transistor. The plurality of memory cells in the first string include a plurality of first memory cells in a first sub-block adjacent to the first select transistor, a plurality of second memory cells in a second sub-block adjacent to the second select transistor, and a first intermediate cell between the first sub-block and the second sub-block. When a write operation is performed in which the first sub-block is set as a selected sub-block, the second sub-block is set as a non-selected sub-block, the first string is set as a non-selected string, and a second string different from the first string is set as a selected string, a first precharge on the first string is performed in a state where the first intermediate cell is turned off, the first select transistor is turned on, and the second select transistor is turned on.

### First Embodiment

FIG. 1 is a block diagram illustrating a configuration of a memory system of a first embodiment.

The memory system of the present embodiment includes a NAND memory 101 and a memory controller 102, as illustrated in FIG. 1. The NAND memory 101 includes a memory cell array 1, a row decoder 2, a word line driver 3, a column decoder 4, a sense amplifier module 5, a data latch module 6, a control circuit 11, a high voltage generator 12, an address register 13, a command register 14, and an input/output (I/O) buffer 15. The NAND memory 101 is an example of a semiconductor storage device.

An operation of the NAND memory 101 is controlled by the memory controller 102. The memory controller 102 operates in response to a request from a host device (not illustrated). For example, the memory controller 102 controls a readout of data from the NAND memory 101 in response to a read request from the host device. In addition, the memory controller 102 controls writing of data to the NAND memory 101 in response to a write request from the host device. Further, the memory controller 102 controls erasing of data from the NAND memory 101 in response to an erase request from the host device.

The memory cell array 1 includes a plurality of memory cells. The NAND memory 101 of the present embodiment is a three-dimensional semiconductor memory in which these memory cells are arranged in a three-dimensional array. In the present embodiment, the memory cell array 1 includes a plurality of blocks, each of the blocks includes a plurality of pages, and each of the pages includes a plurality of memory cells. The block is used as an erase unit for data, and the page is used as a write unit for data and a read unit for data. Further details of the memory cell array 1 will be described later.

The row decoder 2 receives a row address from the address register 13, and decodes the row address. The word line driver 3 supplies a voltage to a word line based on the decoded row address, and drives the word line.

The column decoder 4 receives a column address from the address register 13, and decodes the column address. The column decoder 4 further determines, based on the decoded column address, whether to transfer data retained in the data latch module 6 to a data bus.

During a write operation, the sense amplifier module 5 transfers write data, which is received from the memory controller 102, to the memory cell array 1. During a read operation, the sense amplifier module 5 transfers read data, which is detected from the memory cell array 1, to the memory controller 102. Data is transferred between the sense amplifier module 5 and the memory controller 102 via the data latch module 6.

During a write operation, the data latch module 6 retains the write data acquired from the memory controller 102. The write data retained in the data latch module 6 is transferred to the sense amplifier module 5. During a read operation, the data latch module 6 retains the read data acquired from the sense amplifier module 5. The read data retained in the data latch module 6 is transferred to the memory controller 102.

The control circuit 11 controls various operations of the NAND memory 101. For example, the control circuit 11 controls the operations of the row decoder 2, the word line driver 3, the column decoder 4, the sense amplifier module 5, the data latch module 6, the high voltage generator 12, the I/O buffer 15, and the like based on a command retained in the command register 14. This makes it possible to execute a read operation, a write operation, an erase operation, and the like based on the command.

The high voltage generator 12 generates a high voltage used in a read operation, a write operation, an erase operation, and the like. The high voltage generated by the high voltage generator 12 is supplied to the word line driver 3 and the sense amplifier module 5.

The address register 13 retains address information received by the NAND memory 101 from the memory controller 102. The command register 14 retains a command received by the NAND memory 101 from the memory controller 102.

The I/O buffer 15 buffers a command, address information, and data input from an input terminal, and data to be output from an output terminal. The I/O buffer 15 further transfers the command, the address information, and the data input from the input terminal to the command register 14, the address register 13, and the data bus, respectively.

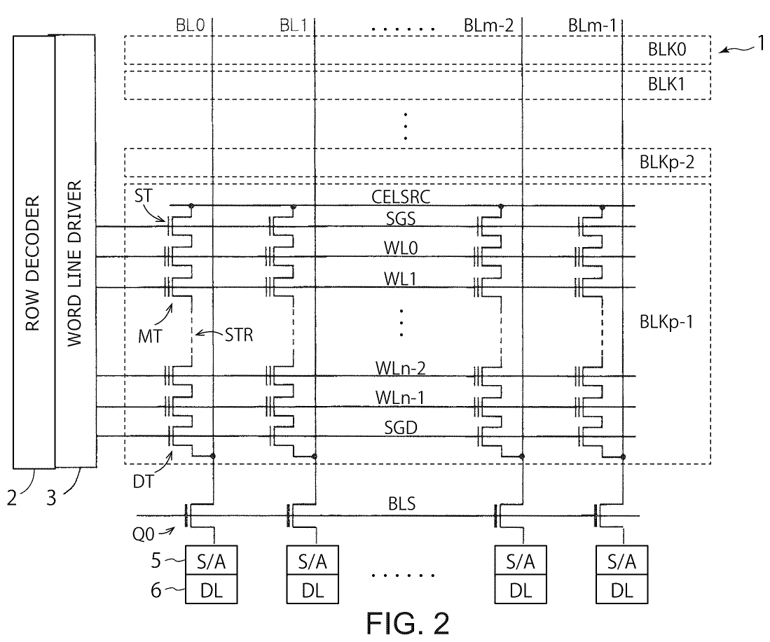

FIG. 2 is a circuit diagram illustrating a configuration of the memory cell array 1 of the first embodiment.

FIG. 2 illustrates p blocks BLK0 to BLKp-1 (where “p” is an integer equal to or greater than 2) in the memory cell array 1. Hereinafter, the configuration of each block will be described using the block BLKp-1 as an example.

The block BLKp-1 includes m (where “m” is an integer equal to or greater than 2) NAND strings STR. Each of the NAND strings STR is arranged between one of m bit lines BL0 to BLm-1 and a cell source line CELSRC. Each of the NAND strings STR includes n (where “n” is an integer equal to or greater than 2) memory cell transistors (memory cells) MT, a source-side select transistor ST, and a drain-side select transistor DT. Each of the memory cell transistors MT is electrically connected to one of n word lines WL0 to WLb 1. The source-side select transistor ST is electrically connected to a source-side select line SGS. The drain-side select transistor DT is electrically connected to a drain-side select line SGD. Each of the NAND strings is an example of a string, such as a first string or a second string, and the source-side select transistor ST and the drain-side select transistor DT are example of first and second select transistors.

FIG. 2 further illustrates m sense amplifiers S/A in the sense amplifier module 5, m data latches DL in the data latch module 6, and m select transistors Q0 electrically connected to a select line BLS. Each of the sense amplifiers can be electrically connected to one of the bit lines BL0 to BLm-1 via the corresponding select transistor Q0. Each of the data latches can be electrically connected to the corresponding sense amplifier.

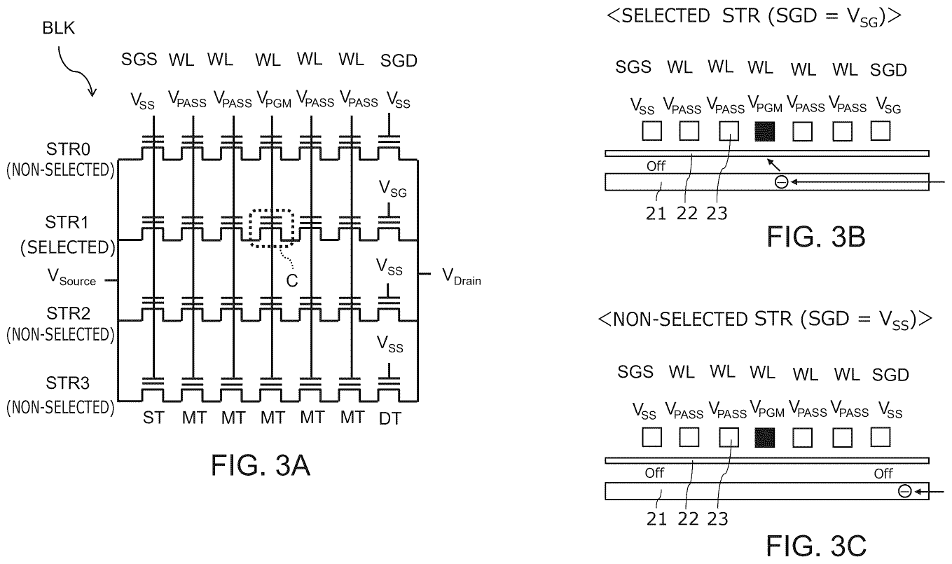

FIGS. 3A to 3C are diagrams for illustrating the write operation of the first embodiment.

FIG. 3A illustrates an example of a block BLK in the memory cell array 1. In FIG. 3A, the block BLK includes four NAND strings STR0 to STR3, and each of the NAND strings STR0 to STR3 includes five memory cells MT, a source-side select transistor ST, and a drain-side select transistor DT. Each of the memory cells MT is electrically connected to one of five word lines WL, the source-side select transistor ST is electrically connected to a source-side select line SGS, and the drain-side select transistor DT is electrically connected to a drain-side select line SGD. Each of the NAND strings STR0 to STR3 is applied with a source voltage V_{Source} via the source-side select transistor ST, and is applied with a drain voltage V_{Drain} via the drain-side select transistor DT.

In FIG. 3A, one memory cell MT in the NAND string STR1 is a selected cell C for the write operation. In this case, the NAND string STR1 is a selected string, and the NAND strings STR0, STR2, and STR3 are non-selected strings. Furthermore, the word line WL of the selected cell C is a selected word line, and the other word lines WL are non-selected word lines. In FIG. 3A, data to be written is written to the selected cell C.

FIG. 3A further illustrates a voltage V_{PGM} applied to the selected word line and a voltage V_{PASS} applied to each of the non-selected word lines. FIG. 3A further illustrates a voltage V_{SG} applied to a gate of the drain-side select transistor DT in the selected string, and a voltage V_{SS} applied to gates of the drain-side select transistor DT in each of the non-selected strings, the source-side select transistor ST in the selected string, and the source-side select transistor ST in each of the non-selected strings. In the present embodiment, the voltage V_{PGM} is a large voltage, the voltage V_{SS} is a small voltage, and the voltage V_{PASS} and the voltage V_{SG} are approximately intermediate voltages. The voltage V_{PGM} is called a write voltage. Data is written to the selected cell C when the voltages V_{PGM}, V_{PASS}, V_{SG}, and V_{SS} are applied to the block BLK.

In each of the NAND strings of the present embodiment, the voltage applied to the gate of the source-side select transistor ST is controlled for each block BLK. For this reason, the same voltage V_{SS} is applied to the gate of the source-side select transistor ST in the selected string and the non-selected string. On the other hand, in each of the NAND strings of the present embodiment, the voltage applied to the gate of the drain-side select transistor DT is controlled for each NAND string. This makes it possible to apply different voltages V_{SG} and V_{SS} to the gate of the drain-side select transistor DT in the selected string and the non-selected string.

FIG. 3B illustrates a selected string in the block BLK, and FIG. 3C illustrates a non-selected string in the block BLK. As illustrated in FIGS. 3B and 3C, each of the NAND strings in the block BLK includes a channel semiconductor layer 21, a charge storage layer 22, and a plurality of electrode layers 23. In each of the NAND strings, the electrode layer 23 in each of the memory cells MT corresponds to a word line WL, the electrode layer 23 in the source-side select transistor ST corresponds to a source-side select line SGS, and the electrode layer 23 in the drain-side select transistor DT corresponds to a drain-side select line SGD. In each of FIGS. 3B and 3C, a quadrangle shown under each symbol “WL” indicates the electrode layer 23 (word line WL) in the memory cell MT, a quadrangle shown under each symbol “SGS” indicates the electrode layer 23 (source-side select line SGS) in the source-side select transistor ST, and a quadrangle shown under each symbol “SGD” indicates the electrode layer 23 (drain-side select line SGD) in the drain-side select transistor DT.

A black quadrangle illustrated in FIG. 3B indicates the electrode layer 23 in the selected cell C. In FIG. 3B, the source-side select transistor ST is turned off by the voltage V_{SS}, and the drain-side select transistor DT is turned on by the voltage V_{SG}. Therefore, charges (electrons) flow from the drain-side select transistor DT into the channel semiconductor layer 21 of the selected string, and charges are injected into the charge storage layer 22 in the selected cell C. This makes it possible to write data to the selected cell C.

A black quadrangle illustrated in FIG. 3C indicates the electrode layer 23 in the non-selected cell that shares the same word line WL as the selected cell C. The selected cell C illustrated in FIG. 3B and the non-selected cell illustrated in FIG. 3C are electrically connected to the same word line WL, and are included in the same page. In FIG. 3C, the source-side select transistor ST is turned off by the voltage V_{SS}, and the drain-side select transistor DT is also turned off by the voltage V_{SS}. Therefore, no charge flows into the channel semiconductor layer 21 of the non-selected string from either the source-side select transistor ST or the drain-side select transistor DT.

The five memory cells MT illustrated in FIG. 3B and the five memory cells MT illustrated in FIG. 3C are all turned on by the voltages V_{PGM} and V_{PASS}.

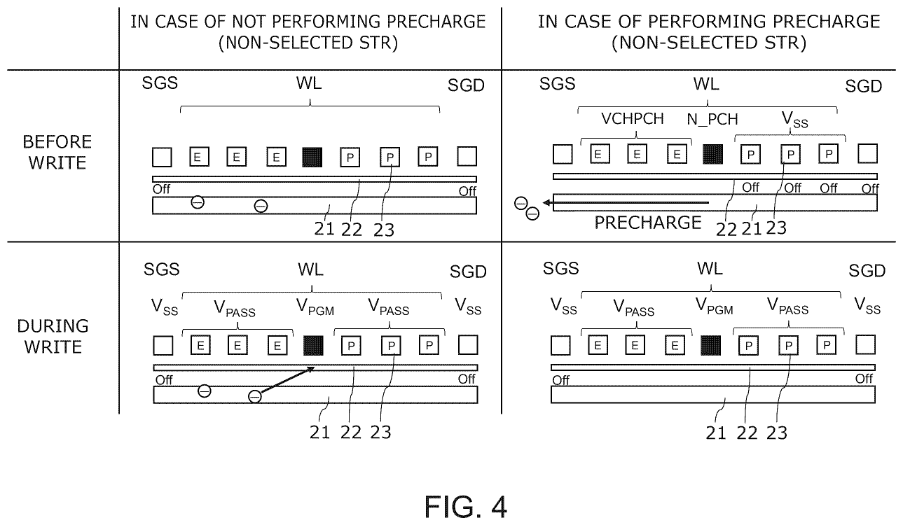

FIG. 4 is a diagram for illustrating a precharge of the first embodiment.

FIG. 4 illustrates non-selected strings before writing and during writing when a precharge is not performed, and non-selected strings before writing and during writing when a precharge is performed. The precharge is a process of, before starting a write operation on a selected string in a certain block BLK, discharging residual charges (residual electrons) from non-selected strings in the block BLK. The precharge is performed, for example, in a manner that the source-side select transistor ST is turned on and residual charges in the non-selected string are discharged from the source-side select transistor ST. In the precharge, for example, a charging process is performed on the non-selected string. In addition, the precharge may be performed not only on the non-selected string but also on the selected string.

In FIG. 4, a symbol “P” indicates that the memory cell MT is a written cell, and a symbol “E” indicates that the memory cell MT is an erased cell. The written cell is a memory cell MT to which data is written. The erased cell is a memory cell MT to which data is not written after being erased. For example, when data is erased from a certain block BLK and then data is written to a certain page in the block BLK, each memory cell MT in the page becomes a written cell. On the other hand, when data is erased from a certain block BLK and then data is not written to any page in the block BLK, each memory cell MT in the block BLK becomes an erased cell.

A left diagram in FIG. 4 illustrates electrons remaining in the channel semiconductor layer 21 of the non-selected string before a write operation to the selected string starts. In this case, since a precharge is not performed, the source-side select transistor ST and the drain-side select transistor DT are turned off. When the write operation to the selected string starts without performing the precharge on the non-selected string, the residual electrons in the non-selected string are injected into the non-selected cell in the same page as the selected cell C by the voltage V_{PGM} (a lower left diagram in FIG. 4). This causes a write error to the non-selected cell.

An upper right diagram in FIG. 4 also illustrates electrons remaining in the channel semiconductor layer 21 of the non-selected string before a write operation to the selected string starts. In this case, since a precharge is performed, the source-side select transistor ST is turned on and the drain-side select transistor DT is turned off. As a result, the residual electrons in the non-selected string are discharged from the source-side select transistor ST by the precharge. This makes it possible to prevent a write error to the non-selected cell in the same page as the selected cell C (a lower right diagram in FIG. 4).

An upper right diagram in FIG. 4 illustrates a voltage N_PCH applied to the non-selected cell in the same page as the selected cell C, a voltage VCHPCH applied to each of erased cells, and a voltage V_{SS} applied to each of written cells. In the present embodiment, the voltages N_PCH, VCHPCH, and V_{SS} are applied to the non-selected string, and thus the precharge is performed on the non-selected string. In this case, each of the written cells is turned off, and each of the memory cells MT other than the written cells is turned on. Each diagram in FIG. 4 illustrates the non-selected string in the block BLK during execution of the write operation, and the data is being written from the right to the left of the string.

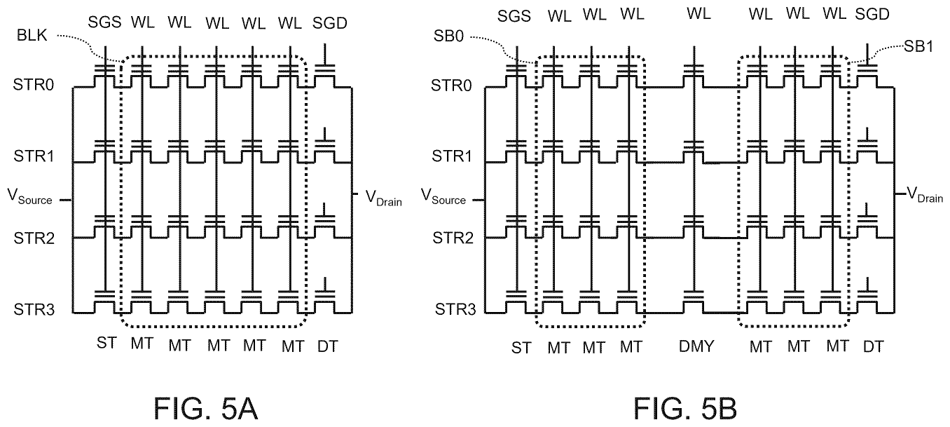

FIGS. 5A and 5B are diagrams for illustrating a sub-block mode of the first embodiment.

FIG. 5A is a diagram for illustrating an operation of the NAND memory 101 when the NAND memory 101 is in a normal mode. In the normal mode, a predetermined operation (for example, a write operation, a read operation, or an erase operation) is performed on each memory cell MT in one block BLK.

FIG. 5B is a diagram for illustrating an operation of the NAND memory 101 when the NAND memory 101 is in a sub-block mode (SBM). In FIG. 5B, each of the NAND strings STR0 to STR3 includes three memory cells MT in a sub-block SB0 adjacent to the source-side select transistor ST, three memory cells MT in a sub-block SB1 adjacent to the drain-side select transistor DT, and one dummy cell DMY between the sub-block SB0 and the sub-block SB1. The sub-blocks SB0 and SB1 are examples of a first sub-block and a second sub-block, respectively. Furthermore, each memory cell MT in the sub-block SB0, each memory cell MT in the sub-block SB1, and the dummy cell DMY are examples of a first memory cell, a second memory cell, and a first intermediate cell, respectively.

In each of the NAND strings illustrated in FIG. 5B, the dummy cell DMY has a structure similar to that of the other memory cells MT, and is electrically connected to the word line WL, similarly to the other memory cells MT. However, the dummy cell DMY is not used in the SBM as a memory cell MT for storing data. FIGS. 5A and 5B illustrate the same block BLK that operates in the normal mode and the SBM. However, FIG. 5A does not illustrate a cell corresponding to the dummy cell DMY illustrated in FIG. 5B, and some of the memory cells MT illustrated in FIG. 5B.

The block BLK illustrated in FIG. 5B includes 12 memory cells MT provided in the sub-block SB0, 12 memory cells MT provided in the sub-block SB1, and four dummy cells DMY provided between the sub-block SB0 and the sub-block SB1. FIG. 5B illustrates three word lines WL for the memory cells MT in the sub-block SB0, three word lines WL for the memory cells MT in the sub-block SB1, and one word line WL for the dummy cells DMY.

In the SBM, a write operation on the sub-block SB0 and a write operation on the sub-block SB1 can be performed independently. For example, the write operation on the sub-block SB0 is not performed, and only the write operation on the sub-block SB1 can be performed. In this case, the write operation is performed on each of the memory cells MT in the sub-block SB1, but the write operation is not performed on each of the memory cells MT in the sub-block SB0. This also applies to a read operation and an erase operation. In the SBM, each of the dummy cells DMY is used as a switch that separates the sub-block SB0 from the sub-block SB1.

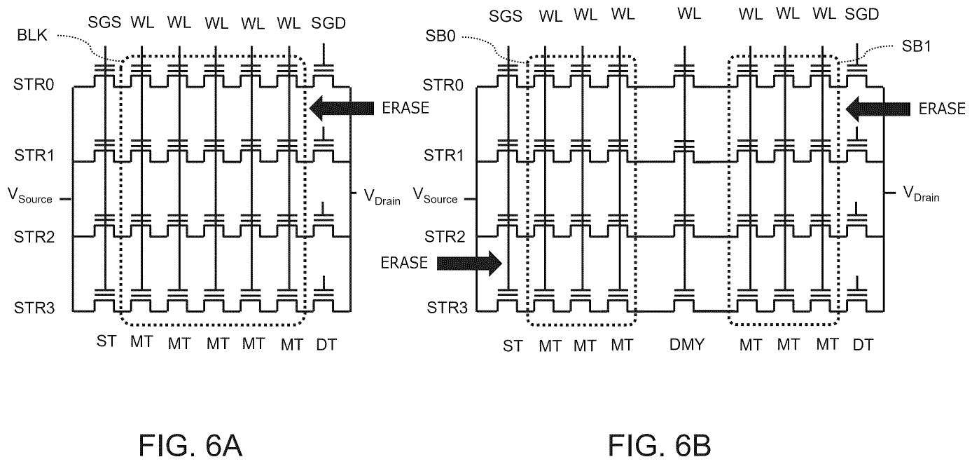

FIGS. 6A and 6B are diagrams for illustrating an erase operation of the first embodiment.

FIG. 6A is a diagram for illustrating an erase operation of the NAND memory 101 when the NAND memory 101 is in a normal mode. In the erase operation in the normal mode, stored data in each of memory cells MT is erased in a batch for each block BLK.

FIG. 6B is a diagram for illustrating an erase operation of the NAND memory 101 when the NAND memory 101 is in an SBM. In the erase operation in the SBM, stored data in each of memory cells MT is erased in a batch for each sub-block. For example, in the erase operation in the SBM, the erase operation on the sub-block SB0 is not performed, and only the erase operation on the sub-block SB1 can be performed.

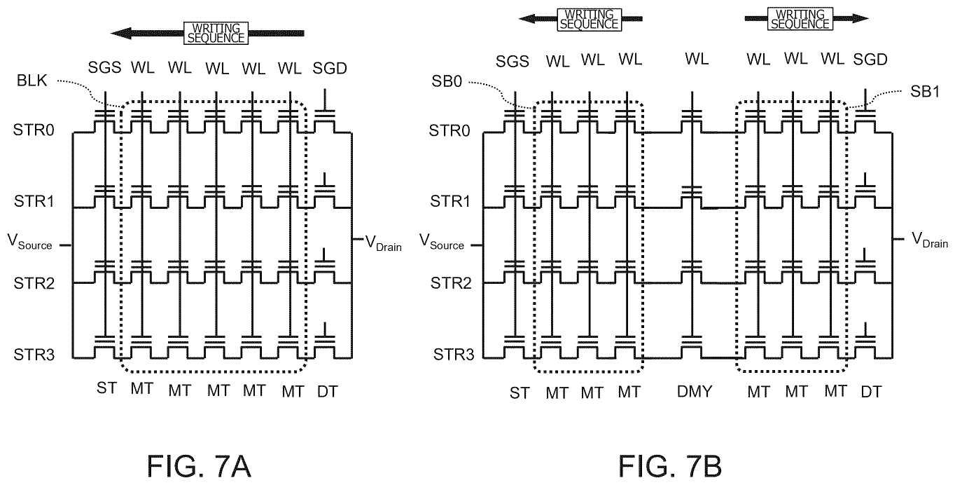

FIGS. 7B and 7B are diagrams for illustrating a write operation of the first embodiment.

FIG. 7A is a diagram for illustrating a write operation of the NAND memory 101 when the NAND memory 101 is in a normal mode. In the write operation in the normal mode, data is written to each of memory cells MT for each page, that is, for each word line WL. In FIG. 7A, writing to one block BLK proceeds from a right side to a left side, that is, from a drain side to a source side.

FIG. 7B is a diagram for illustrating a write operation of the NAND memory 101 when the NAND memory 101 is in an SBM. In the write operation in the SBM, data is also written to each of memory cells MT for each page. In FIG. 7B, writing to the sub-block SB0 proceeds from a right side to a left side (from a dummy side to a source side), and writing to the sub-block SB1 proceeds from a left side to a right side (from a dummy side to a drain side). In the write operation in the SBM, the writing to the other sub-block can begin before the writing to one sub-block is completed.

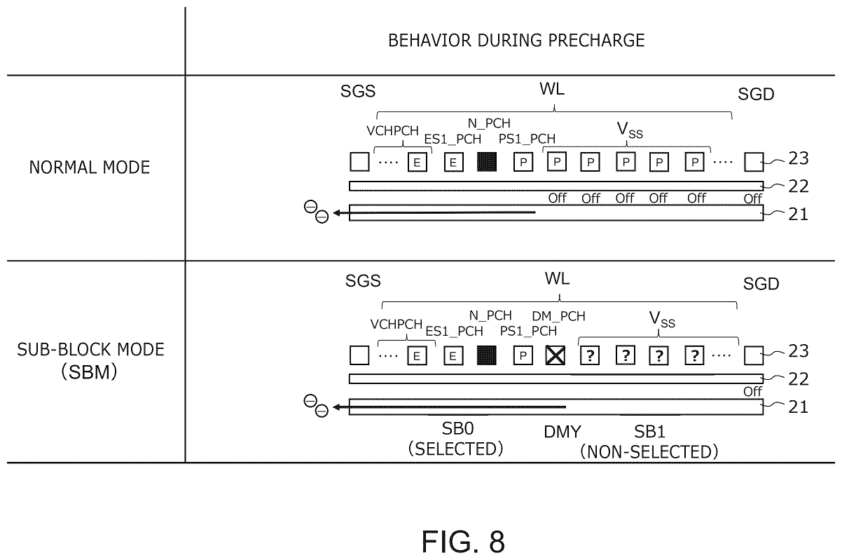

FIG. 8 is a diagram for illustrating a problem of the precharge of the first embodiment.

An upper diagram in FIG. 8 illustrates a non-selected string in a case of performing a precharge in a normal mode. The upper diagram further illustrates the voltage N_PCH applied to the non-selected cell in the same page as the selected cell C, the voltage VCHPCH applied to each of erased cells, and the voltage V_{SS} applied to each of the written cells, as in FIG. 4. However, in the upper diagram, a voltage ES1_PCH is applied to the erased cell adjacent to the non-selected cell, and a voltage PS1_PCH is applied to the written cell adjacent to the non-selected cell. In the upper diagram, each of the written cells applied with the voltage V_{SS} and the drain-side select transistor DT are turned off, and the other memory cells MT and the source-side select transistor ST are turned on. In the precharge, residual charges in the non-selected string are discharged from the source-side select transistor ST.

A lower diagram in FIG. 8 illustrates a non-selected string in a case of performing a precharge in an SBM. In the lower diagram, a sub-block SB0 is set as a selected sub-block to which data is written in the write operation of FIG. 8, and the sub-block SB1 is set as a non-selected sub-block to which data is not written in the write operation of FIG. 8. The lower diagram illustrates voltages N_PCH, VCHPCH, V_{SS}, ES1_PCH, and PS1_PCH. However, each memory cell MT in the sub-block SB1 is a cell being in any state which may be either a written cell or an erased cell. Each memory cell MT in the sub-block SB1 is applied with a voltage V_{SS}. The lower diagram further illustrates a voltage DM_PCH applied to a dummy cell DMY indicated by a quadrangle marked with X. In the lower diagram, the drain-side select transistor DT is turned off, and the dummy cell DMY and the source-side select transistor ST are turned on. In the precharge, residual charges in the non-selected string are also discharged from the source-side select transistor ST.

In the upper diagram in FIG. 8, all the memory cells MT between the above-described non-selected cell indicated by a black quadrangle and the drain-side select transistor DT are written cells. On the other hand, in the lower diagram in FIG. 8, all the memory cells MT between the above-described non-selected cell indicated by the black quadrangle and the drain-side select transistor DT are not necessarily written cells. As a result, a problem may occur as will be described later.

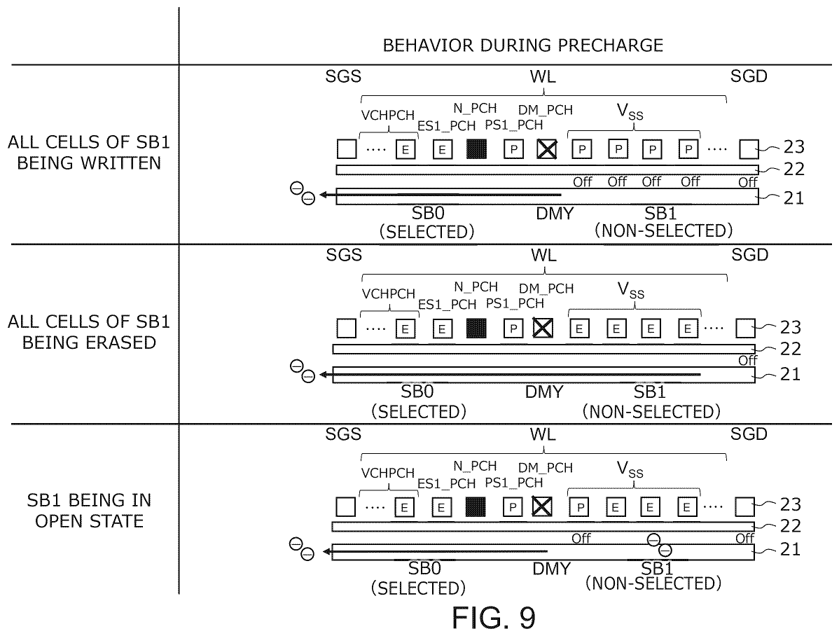

FIG. 9 is another diagram for illustrating the problem of the precharge of the first embodiment.

An upper diagram in FIG. 9 illustrates a first example of a non-selected string in a case of performing a precharge in an SBM. In this example, all memory cells MT in a sub-block SB1 are written cells. Therefore, all the memory cells MT in the sub-block SB1 are turned off.

A middle diagram in FIG. 9 illustrates a second example of a non-selected string in a case of performing a precharge in an SBM. In this example, all memory cells MT in a sub-block SB1 are erased cells. Therefore, all the memory cells MT in the sub-block SB1 are turned on.

A lower diagram in FIG. 9 illustrates a third example of a non-selected string in a case of performing a precharge in an SBM. In this example, one memory cell MT in a sub-block SB1 is a written cell, and the other memory cells MT in the sub-block SB1 are erased cells. This state occurs when writing to the sub-block SB1 starts but the writing to the sub-block SB1 is not completed (=in a case of halfway writing). This state is called an open state. In this example, the written cell in the sub-block SB1 is turned off, and the erased cells in the sub-block SB1 are turned on.

The lower diagram in FIG. 9 illustrates electrons remaining in the channel semiconductor layer 21 of the non-selected string in the sub-block SB1. In this example, electrons resulting from the halfway writing remain near the erased cells in the sub-block SB1. On the other hand, in this example, since the written cell in the sub-block SB1 is turned off, the electrons cannot pass through the channel semiconductor layer 21 near the written cell. Therefore, the electrons cannot be discharged from the source-side select transistor ST by the precharge. As a result, electrons remain in the non-selected string after the precharge.

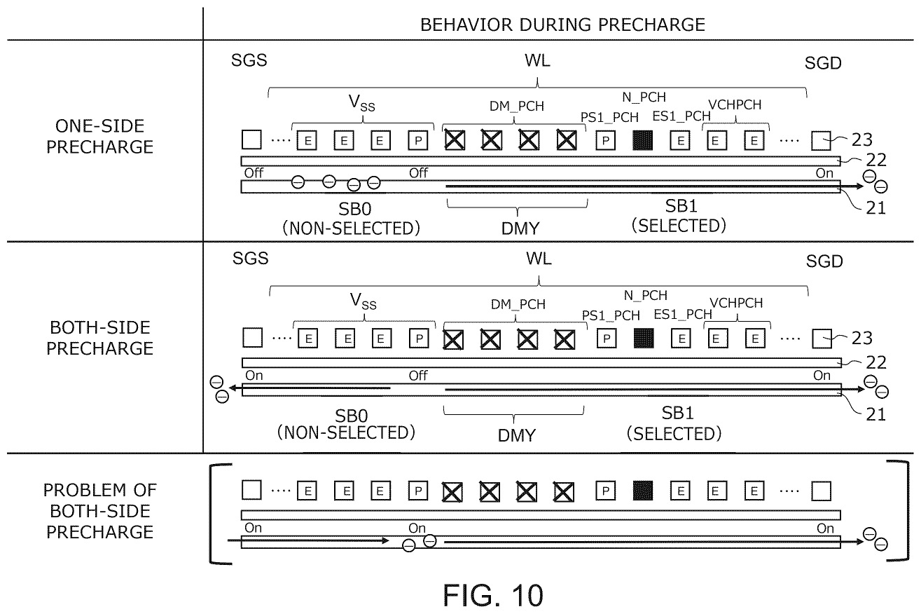

FIG. 10 is another diagram for illustrating the problem of the precharge of the first embodiment.

An upper diagram in FIG. 10 illustrates a non-selected string in a case of performing one-side precharge in an SBM. In the upper diagram, the sub-block SB1 is set as a selected sub-block, the sub-block SB0 is set as a non-selected sub-block, and the sub-block SB0 is in an open state. In the upper diagram, the non-selected string includes a plurality of dummy cells DMY adjacent to each other, but may include only one dummy cell DMY as described above. In the one-side precharge, the precharge on the non-selected string is performed from only one of the source side and the drain side, as described with reference to FIGS. 4, 8, and 9. In the upper diagram, the source-side select transistor ST is turned off, and the drain-side select transistor DT is turned on, whereby the precharge on the non-selected string is performed only from the drain side. As a result, electrons remain as described in the sub-block SB0 after the precharge.

A lower diagram in FIG. 10 illustrates a non-selected string in a case of performing a both-side precharge in an SBM. In the both-side precharge, the precharge on the non-selected string is performed from both the source side and the drain side. In the lower diagram, the source-side select transistor ST and the drain-side select transistor DT are turned on, and thus the precharge on the non-selected string is performed from the source side and the drain side. This makes it possible to discharge electrons in the sub-block SB0 from the source side and to prevent electrons to remain in the sub-block SB0 after the precharge.

A diagram outside the box in FIG. 10 illustrates a problem in a case of performing the both-side precharge in the SBM. When the both-side precharge is performed in a state where the sub-block SB0 is in an open state, the written cell in the sub-block SB0 may be easily turned on. In this case, when the written cell in the sub-block SB0 is turned on, electrons in the sub-block SB0 moves toward the drain side, resulting in causing a problem of through-current. The through-current is a cause of electron residue.

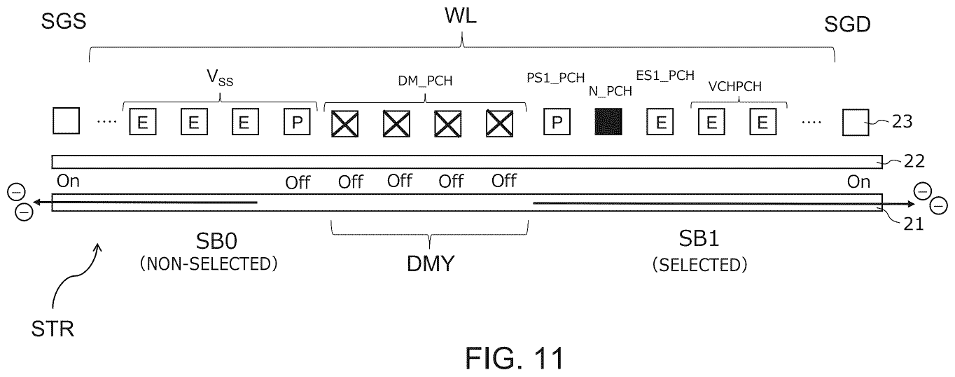

FIG. 11 is a diagram for illustrating the operation of the memory cell array 1 of the first embodiment.

FIG. 11 illustrates an example of the precharge on the non-selected string STR of the present embodiment. In FIG. 11, the both-side precharge is performed in the SBM, similarly to the lower diagram in FIG. 10. However, a voltage DM_PCH illustrated in FIG. 11 is set to be smaller than the voltage DM_PCH illustrated in FIG. 10. As a result, each of dummy cells DMY illustrated in FIG. 11 is turned off.

Accordingly, the precharge on the non-selected string STR of the present embodiment is performed in a state where each of the dummy cells DMY is turned off, the source-side select transistor ST is turned on, and the drain-side select transistor DT is turned on. This makes it possible to provide advantages of the both-side precharge while preventing drawbacks of the both-side precharge. For example, each of the dummy cells DMY is turned off, whereby it is possible to discharge the residual electrons in the non-selected string STR from the source side and the drain side while preventing the through-current. As described above, the present embodiment makes it possible to suitably perform the precharge in the SBM, and therefore it is possible to suitably perform the write operation in the SBM. The write operation, the precharge, the SBM, and the like of the present embodiment are controlled by the control circuit 11 illustrated in FIG. 1, for example. The precharge of the present embodiment is an example of a first precharge.

In the precharge on the non-selected string STR of the present embodiment, only some of the dummy cells DMY may be turned off instead of turning off all of the dummy cells DMY. Even when some of the dummy cells DMY are turned on, the drawbacks of the both-side precharge can be prevented. However, since the channel semiconductor layer 21 can be more reliably cut off near the dummy cells DMY when a larger number of dummy cells DMY are turned off, it is preferable to turn off all of the dummy cells DMY in the precharge.

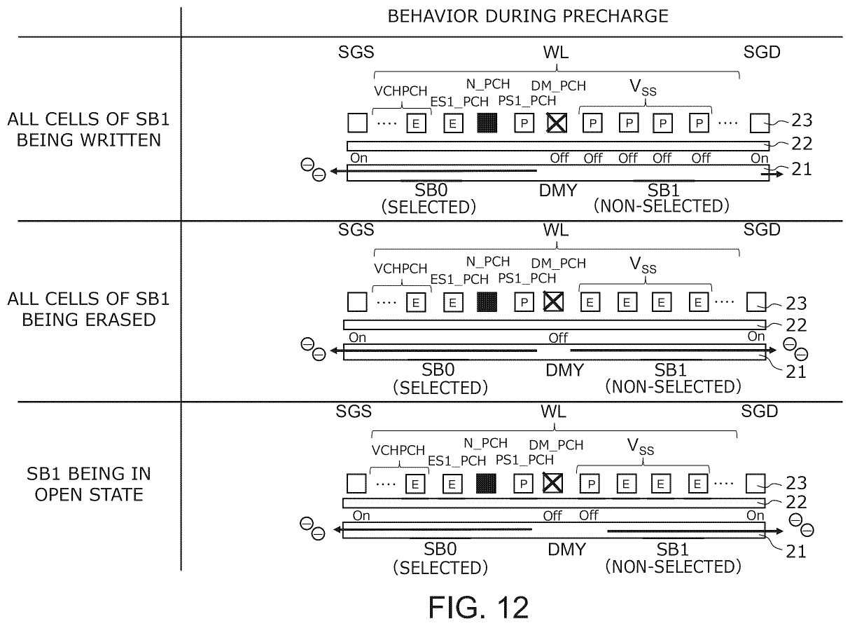

FIG. 12 is another diagram for illustrating the operation of the memory cell array 1 of the first embodiment.

An upper diagram in FIG. 12 illustrates a first example of a non-selected string in a case of performing a precharge in an SBM in the present embodiment. In this example, the sub-block SB0 is set as a selected sub-block, the sub-block SB1 is set as a non-selected sub-block, and all memory cells MT in the sub-block SB1 are written cells. Therefore, all of the memory cells MT in the sub-block SB1 are turned off. In this example, a precharge is performed in a state where the dummy cell DMY is turned off, the source-side select transistor ST is turned on, and the drain-side select transistor DT is turned on.

A middle diagram in FIG. 12 illustrates a second example of a non-selected string in a case of performing a precharge in an SBM in the present embodiment. In this example, the sub-block SB0 is set as a selected sub-block, the sub-block SB1 is set as a non-selected sub-block, and all memory cells MT in the sub-block SB1 are erased cells. Therefore, all of the memory cells MT in the sub-block SB1 are turned on. In this example, a precharge is performed in a state where the dummy cell DMY is turned off, the source-side select transistor ST is turned on, and the drain-side select transistor DT is turned on.

A lower diagram in FIG. 12 illustrates a third example of a non-selected string in a case of performing a precharge in an SBM in the present embodiment. In this example, the sub-block SB0 is set as a selected sub-block, the sub-block SB1 is set as a non-selected sub-block, one memory cell MT in the sub-block SB1 is a written cell, and the other memory cells MT in the sub-block SB1 are erased cells. In this example, the sub-block SB1 is in an open state, the written cell in the sub-block SB1 is turned off, and the erased cells in the sub-block SB1 are turned on. In this example, a precharge is performed in a state where the dummy cell DMY is turned off, the source-side select transistor ST is turned on, and the drain-side select transistor DT is turned on.

As described above, in all of the first, second, and third examples in FIG. 12, the precharge is performed in a state where the dummy cell DMY is turned off, the source-side select transistor ST is turned on, and the drain-side select transistor DT is turned on.

### (1) First Modification of First Embodiment

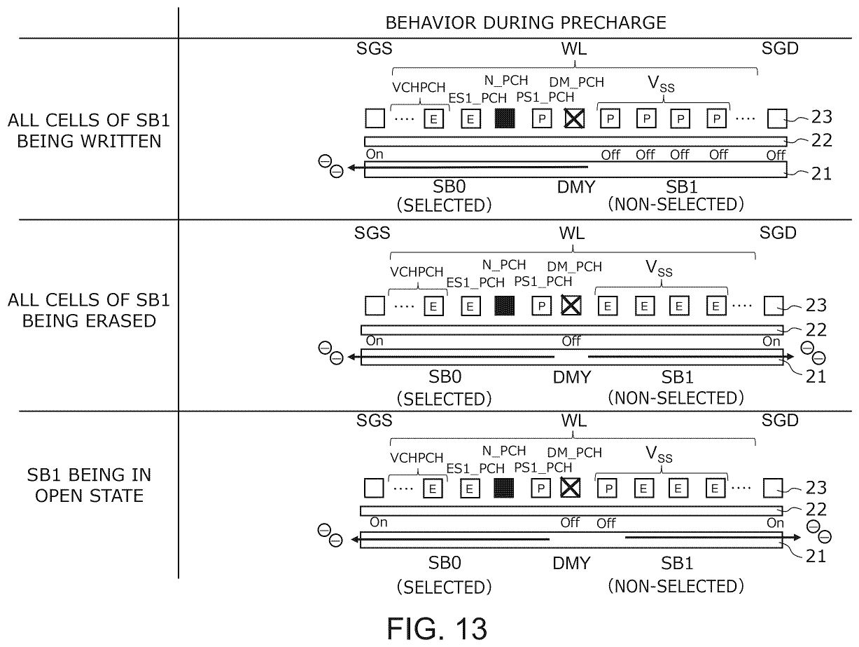

FIG. 13 is a diagram for illustrating an operation of the memory cell array 1 of a first modification of the first embodiment.

Upper, middle, and lower diagrams in FIG. 13 illustrate first, second, and third examples of non-selected strings in a case of performing a precharge in an SBM of the present modification, respectively. The precharges of the second and third examples in FIG. 13 are the same as the precharges of the second and third examples in FIG. 12, but the precharge of the first example in FIG. 13 is different from the precharge of the first example in FIG. 12. In FIG. 13, the precharges of the second and third examples are examples of a first precharge, and the precharge of the first example is an example of a second precharge.

In the first example in FIG. 13, the sub-block SB0 is set as a selected sub-block, the sub-block SB1 is set as a non-selected sub-block, and all memory cells MT in the sub-block SB1 are written cells. Therefore, the sub-block SB1 includes no erased cell, and all of the memory cells MT in the sub-block SB1 are turned off. In this example, the precharge is performed in a state where the dummy cell DMY is turned off, the source-side select transistor ST is turned on, and the drain-side select transistor DT is turned off. The both-side precharge is performed in the second and third examples in FIG. 13, and one-side precharge is performed in the first example in FIG. 13.

Here, the first example in FIG. 12 is compared with the first example in FIG. 13.

In the first example in FIG. 12, the sub-block SB1 does not include erased cells. Therefore, this example does not cause a problem in which electrons remain near the erased cells in the sub-block SB1 (for example, see the lower diagram in FIG. 9). For this reason, the precharge from the drain side is useless in this example. In other words, the operation of turning on the drain-side select transistor DT is useless in this example.

On the other hand, in the first example in FIG. 13, the precharge from the source side is performed, but the precharge from the drain side is not performed. This makes it possible to avoid the useless operation of turning on the drain-side select transistor DT when the sub-block SB1 does not include the erased cells.

In the memory system in FIG. 1, the memory controller 102 manages information indicating whether each of the memory cells MT in the memory cell array 1 is a written cell or an erased cell. In this modification, the NAND memory 101 receives this information from the memory controller 102, and performs the precharge of the first to third examples in FIG. 13 based on the received information. For example, when the information indicates that a certain non-selected string includes only the written cells in the sub-block SB1, one-side precharge is performed on the non-selected string. On the other hand, when the information indicates that a certain non-selected string includes the erased cells in the sub-block SB1, both-side precharge is performed on the non-selected string. Such an operation of the NAND memory 101 is controlled by the control circuit 11, for example.

Furthermore, the one-side precharge in FIG. 13 may be also applied to a case where the non-selected string is in a halfway writing state in the sub-block SB1 as in the third example, but the non-selected string includes only the written cells in the sub-block SB1. This makes it possible to avoid the useless operation of turning on the drain-side select transistor DT in this case.

On the other hand, the operation in FIG. 12 may be performed when the above-described information is notified from the memory controller 102 to the NAND memory 101, or may be performed when the information is not notified from the memory controller 102 to the NAND memory 101. Since both-side precharge is performed in any of the first to third examples in FIG. 12, the NAND memory 101 can perform the operation in FIG. 12 without using the above-described information. In other words, when performing the operation in FIG. 12, the NAND memory 101 may perform the precharge on the non-selected string after grasping the state of each of the memory cells MT in the sub-block SB1, or may perform the precharge on the non-selected string without grasping the state of each of the memory cells MT in the sub-block SB1.

### (2) Second Modification of First Embodiment

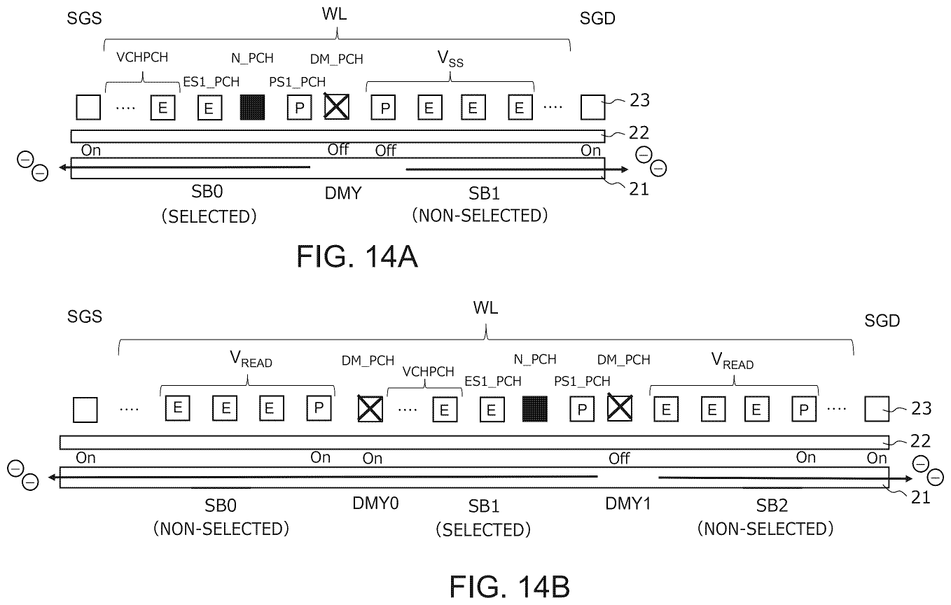

FIGS. 14A and 14B are diagrams for illustrating an operation of the memory cell array 1 of a second modification of the first embodiment.

FIG. 14A illustrates a first example of a non-selected string in a case of performing a precharge in an SBM. In the SBM of this example, each NAND string includes a plurality of memory cells MT in a sub-block SB0, a plurality of memory cells MT in a sub-block SB1, and one dummy cell DMY between the sub-block SB0 and the sub-block SB1. In FIG. 14A, the sub-block SB0 is set as a selected sub-block, the sub-block SB1 is set as a non-selected sub-block, one memory cell MT in the sub-block SB1 is a written cell, and the other memory cells MT in the sub-block SB1 are erased cells. In FIG. 14A, both-side precharge on the non-selected string is performed as in the third example in FIG. 12.

FIG. 14B illustrates a second example of a non-selected string in a case of performing a precharge in an SBM. In the SBM of this example, each NAND string includes a plurality of memory cells MT in a sub-block SB0, a plurality of memory cells MT in a sub-block SB1, and a plurality of memory cells MT in a sub-block SB2. In this example, the sub-block SB0 is adjacent to a source-side select transistor ST, the sub-block SB2 is adjacent to a drain-side select transistor DT, and the sub-block SB1 is located between the sub-block SB0 and the sub-block SB2. In FIG. 14B, the sub-block SB0 is an example of a first sub-block, and each of the memory cells MT in the sub-block SB0 is an example of a first memory cell. In addition, the sub-block SB2 is an example of a second sub-block, and each of the memory cells MT in the sub-block SB2 is an example of a second memory cell. In addition, the sub-block SB1 is an example of a third sub-block, and each of the memory cells MT in the sub-block SB1 is an example of a third memory cell.

In the SBM in FIG. 14B, each NAND string further includes one dummy cell DMY0 between the sub-block SB0 and the sub-block SB1, and one dummy cell DMY1 between the sub-block SB1 and the sub-block SB2. Details of the dummy cells DMY0 and DMY1 are similar to those of the dummy cell DMY described above. In FIG. 14B, the dummy cell DMY0 is an example of a first intermediate cell, and the dummy cell DMY1 is an example of a second intermediate cell.

In the SBM in FIG. 14B, a precharge when the sub-block SB0 is the selected sub-block and a precharge when the sub-block SB2 is the selected sub-block are performed in the same manner as the precharge in FIGS. 12 or 13. For example, when the sub-block SB0 in FIG. 14B is the selected sub-block, the sub-block SB0 in FIG. 14B is controlled in the same manner as the sub-block SB0 in FIGS. 12 or 13, the sub-blocks SB1 and SB2 in FIG. 14B are controlled in the same manner as the sub-block SB1 in FIGS. 12 or 13, and the dummy cell DMY0 in FIG. 14B is controlled in the same manner as the dummy cell DMY in FIGS. 12 or 13. In addition, the dummy cell DMY1 in FIG. 14B is set to be turned on. This also applies to the precharge when the sub-block SB2 in FIG. 14B is the selected sub-block.

On the other hand, the precharge when the sub-block SB1 is the selected sub-block will be described with reference to FIG. 14B. In FIG. 14B, the sub-block SB0 is set as a non-selected sub-block, the sub-block SB1 is set as a selected sub-block, and the sub-block SB2 is set as a non-selected sub-block. In FIG. 14B, the sub-blocks SB0 and SB2 are also in an open state.

In the SBM in FIG. 14B, writing to the selected string proceeds from a right side to a left side in the sub-block SB1. Thus, the memory cells MT to the right of a black quadrangle are written cells, and the memory cells MT to the left of the black quadrangle are erased cells. The black quadrangle represents a non-selected cell in the same page as the selected cell C as described above. In FIG. 14B, both-side precharge on the non-selected string is performed in a state where the dummy cell DMY0 is turned on and the dummy cell DMY1 is turned off. However, in FIG. 14B, a voltage V_{READ} used in the read operation is applied to a gate of each of the memory cells MT in the sub-blocks SB0 and SB2, and as a result, each of the written cells in the sub-blocks SB0 and SB2 is also turned on. The precharge in FIG. 14B can also be applied when the sub-blocks SB0 and SB2 are not in the open state.

In the SBM of the present embodiment, each of the blocks BLK may be divided into four or more sub-blocks. In this case, the sub-block adjacent to the source-side select transistor ST is controlled in the same manner as the sub-block SB0 in FIG. 14B, the sub-block adjacent to the drain-side select transistor DT is controlled in the same manner as the sub-block SB2 in FIG. 14B, and the other sub-blocks are controlled in the same manner as the sub-block SB1 in FIG. 14B.

As described above, the precharge of the present embodiment is performed by the both-side precharge in a state where the dummy cell DMY is turned off, for example, as illustrated in FIG. 12 and the like. Therefore, the present embodiment makes it possible to appropriately perform the precharge in the SBM, and thus, to appropriately perform the write operation in the SBM.

### Second Embodiment

A memory system of the present embodiment has a configuration similar to the memory system of the first embodiment. Accordingly, the contents described with reference to FIGS. 1 to 14B are also applied to the memory system of the present embodiment.

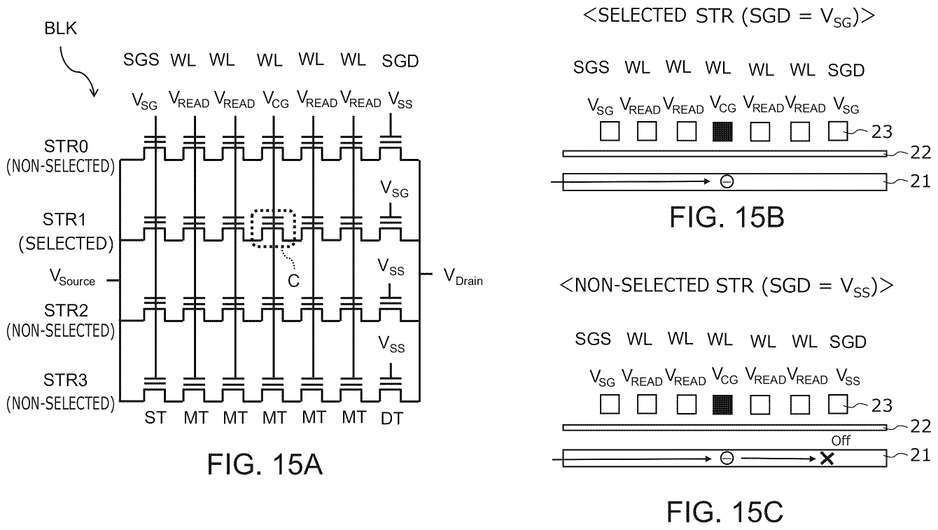

FIGS. 15A to 15C are diagrams for illustrating a read operation of a second embodiment.

FIG. 15A illustrates an example of a block BLK in the memory cell array 1, as in FIG. 3A and the like. In FIG. 15A, one memory cell MT in the NAND string STR1 is a selected cell C for a read operation. In this case, the NAND string STR1 is a selected string, and the NAND strings STR0, STR2, and STR3 are non-selected strings. Furthermore, the word line WL of the selected cell C is a selected word line, the other word lines WL are non-selected word lines. In FIG. 15A, data to be read is read out from the selected cell C.

FIG. 15A further illustrates a voltage V_{CG} applied to the selected word line and a voltage V_{READ} applied to each of the non-selected word lines. FIG. 15A further illustrates a voltage V_{SG} applied to gates of the drain-side select transistor DT in the selected string, the source-side select transistor ST in the selected string, and the source-side select transistor ST in each of the non-selected strings, and a voltage V_{SS} applied to a gate of the drain-side select transistor DT in each of the non-selected strings. In the present embodiment, the voltage V_{CG} is a voltage of any magnitude, the voltage V_{SS} is a small voltage, and the voltage V_{READ} and the voltage V_{SG} are approximately intermediate voltages. The voltage V_{CG} is called a read voltage. Data is read out from the selected cell C when the voltages V_{CG}, V_{READ}, V_{SG}, and V_{SS} are applied to the block BLK. In FIG. 15A, a row (NAND string) is selected by the voltage V_{SG}, and a column (word line) is selected by the voltage V_{CG}.

In each of the NAND strings of the present embodiment, the voltage applied to the gate of the source-side select transistor ST is controlled for each block BLK. For this reason, the same voltage V_{SG} is applied to the gate of the source-side select transistor ST in the selected string and the non-selected string. On the other hand, in each of the NAND strings of the present embodiment, the voltage applied to the gate of the drain-side select transistor DT is controlled for each NAND string. This makes it possible to apply different voltages V_{SS} and V_{SG} to the gate of the drain-side select transistor DT in the selected string and the non-selected string.

FIG. 15B illustrates a selected string in the block BLK as in FIG. 3B and the like, and FIG. 15C illustrates a non-selected string in the block BLK as in FIG. 3C and the like. In each of FIGS. 15B and 15C, a quadrangle shown under each symbol “WL” indicates the electrode layer 23 (word line WL) in the memory cell MT, a quadrangle shown under each symbol “SGS” indicates the electrode layer 23 (source-side select line SGS) in the source-side select transistor ST, and a quadrangle shown under each symbol “SGD” indicates the electrode layer 23 (drain-side select line SGD) in the drain-side select transistor DT.

A black quadrangle illustrated in FIG. 15B indicates the electrode layer 23 in the selected cell C. In FIG. 15B, the source-side select transistor ST is turned on by the voltage V_{SG}, the drain-side select transistor DT is turned on by the voltage V_{SG}, and each of the memory cells MT other than the selected cell C is turned on by the voltage V_{READ}. In this case, a current flows through the selected string when the voltage V_{CG} is greater than a threshold voltage of the selected cell C, but a current does not flow through the selected string when the voltage V_{CG} is smaller than the threshold voltage of the selected cell C. This makes it possible to determine a value of data in the selected cell C from a result of whether the current flows through the selected string. In other words, data can be read out from the selected cell C.

A black quadrangle illustrated in FIG. 15C indicates the electrode layer 23 in the non-selected cell that shares the same word line WL as the selected cell C. The selected cell C illustrated in FIG. 15B and the non-selected cell illustrated in FIG. 15C are electrically connected to the same word line WL, and are included in the same page. In FIG. 15C, the source-side select transistor ST is turned on by the voltage V_{SG}, the drain-side select transistor DT is turned off by the voltage V_{SS}, and each of the memory cells MT other than the non-selected cell is turned on by the voltage V_{READ}. In this case, since the drain-side select transistor DT is turned off, no current flows through the non-selected string.

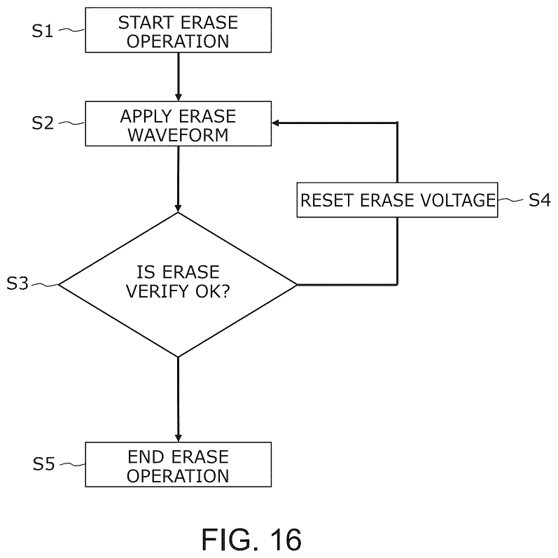

FIG. 16 is a flowchart for illustrating an erase operation of the second embodiment.

When an erase operation is started for a certain block BLK (step S1), an erase waveform is applied to a gate of each of the memory cells MT in the block BLK using a predetermined erase voltage (step S2). This erases data from each of the memory cells MT. The data is erased by the method illustrated in FIG. 6A, for example.

Next, an erase verify is performed on each of the memory cells MT (step S3). In the erase verify, data is read out from each of the memory cells MT to determine whether data is erased from each of the memory cells MT. The data is read out by the methods illustrated in FIGS. 15A to 15C, for example.

When the erase verify of any one of the memory cells MT in the above-described block BLK is NG, that is, when data is not erased from any one of the memory cells MT, the erase voltage is reset (step S4). Then, steps S2 and S3 are performed again using the reset erase voltage.

On the other hand, when the erase verify of all of the memory cells MT in the above-described block BLK is OK, that is, when data is erased from all of the memory cells MT, the erase operation on the block BLK ends (step S5).

The data may be erased in FIG. 16 by the method (SBM) illustrated in FIG. 6B instead of the method (normal mode) illustrated in FIG. 6A. In this case, the erase operation in FIG. 16 is performed for each sub-block. The erase operation, the erase verify, the SBM, and the like of the present embodiment are controlled by the control circuit 11 illustrated in FIG. 1, for example.

The precharge of the first embodiment is performed on the non-selected string, whereas the erase verify of the present embodiment is performed on the selected string. In the present embodiment, the data is read out from the selected cell C, whereby the erase verify is performed on the selected cell C to determine whether the data is erased from the selected cell C. In the present embodiment, when the erase verify is performed on the selected string, a voltage is applied to the selected string as illustrated in FIG. 15B, and a voltage is applied to the non-selected string as illustrated in FIG. 15C.

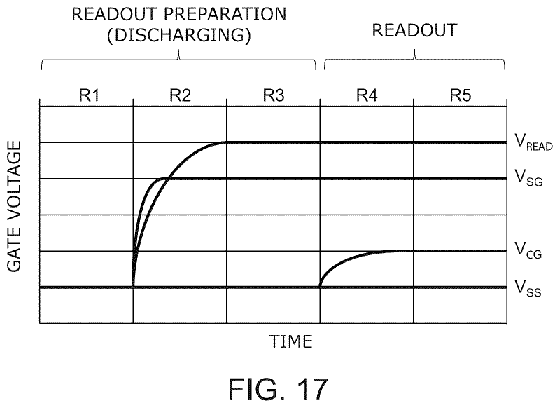

FIG. 17 is a graph for illustrating an erase verify operation of the second embodiment.

FIG. 17 illustrates a change in voltages V_{CG}, V_{PASS}, V_{SG}, V_{SS} (gate voltage) used in the erase verify operation with time. FIG. 17 further illustrates five time ranges R1 to R5 in the erase verify operation. Ranges R1 to R3 correspond to a readout preparation period, and ranges R4 and R5 correspond to a readout period. In the erase verify operation, for example, a discharging process is performed on the selected string. In FIG. 17, the voltage V_{READ} and the voltage V_{SG} rise in the range R2, the voltage V_{CG} rises in the range R4, and the voltage V_{SS} is constant in the ranges R1 to R5.

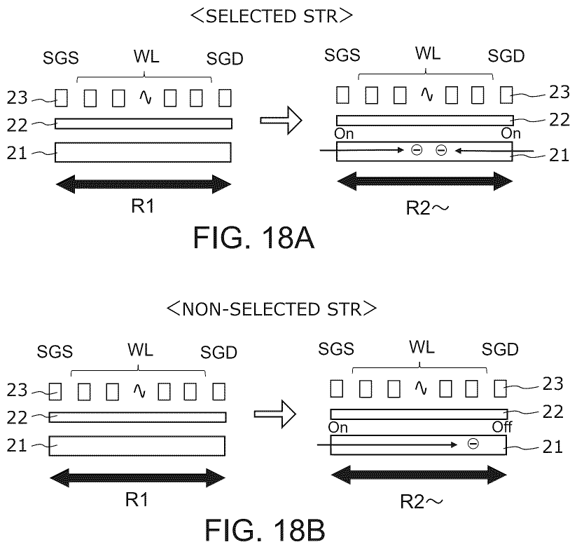

FIGS. 18A and 18B are diagrams for illustrating the erase verify operation of the second embodiment.

FIG. 18A illustrates a selected string in the ranges R1 and R2. An example of the selected string illustrated in FIG. 18A is the NAND string STR1 illustrated in FIG. 15A.

In the range R2 in FIG. 18A, the source-side select transistor ST and the drain-side select transistor DT are turned on, and electrons flow into the selected string from the source side and the drain side. This causes a potential of the channel semiconductor layer 21 of the selected string to decrease (discharge). Thereafter, the potential of the entire channel semiconductor layer 21 of the selected string decreases to a potential of the source and the drain, and reaches equilibrium. As a result, the readout preparation is completed in the range R3.

FIG. 18B illustrates non-selected strings in the ranges R1 and R2. Examples of the non-selected strings illustrated in FIG. 18B are the NAND strings STR0, STR2, and STR3 illustrated in FIG. 15A.

In the range R2 in FIG. 18B, the source-side select transistor ST is turned on, the drain-side select transistor DT is turned off, and electrons flow into the non-selected strings from the source side. This causes a potential of the channel semiconductor layer 21 of the non-selected strings to decrease (discharge). Thereafter, the potential of the entire channel semiconductor layer 21 of the non-selected strings decreases to a potential of the source, and reaches equilibrium. As a result, the readout preparation is completed in the range R3.

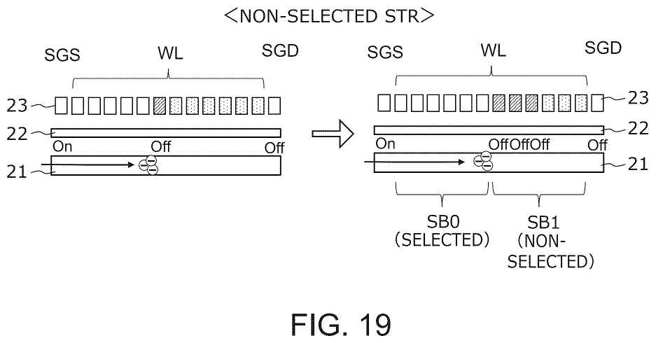

FIG. 19 is another diagram for illustrating the erase verify operation of the second embodiment.

A left diagram in FIG. 19 illustrates a non-selected string in the range R2, as in FIG. 18B. In the left diagram, a quadrangle with diagonal hatching indicates a memory cell MT that is difficult to turn on, and quadrangle with dotted hatching indicate a plurality of memory cells MT located to the right of the memory cell MT that is difficult to turn on. As illustrated in the left diagram, when the memory cell MT that is difficult to turn on is present in the non-selected string, the potential of the channel semiconductor layer 21 becomes high in the region to the right of the memory cell MT that is difficult to turn on, causing a write error.

A right diagram in FIG. 19 also illustrates a non-selected string in the range R2. The right diagram illustrates an example of the non-selected string that operates in the SBM. In the right diagram, the sub-block SB0 is set as a selected sub-block, the sub-block SB1 is set as a non-selected sub-block, and the sub-block SB1 is in an open state. In the right diagram, quadrangles with diagonal hatching indicate a plurality of written cells, and quadrangle with dotted hatching indicate a plurality of erased cells located to the right of these written cells.

The write error described with reference to the left diagram in FIG. 19 easily occurs in the state in the right diagram in FIG. 19. In other words, the write error in the erase verify easily occurs in the non-selected sub-block being in an open state in the SBM.

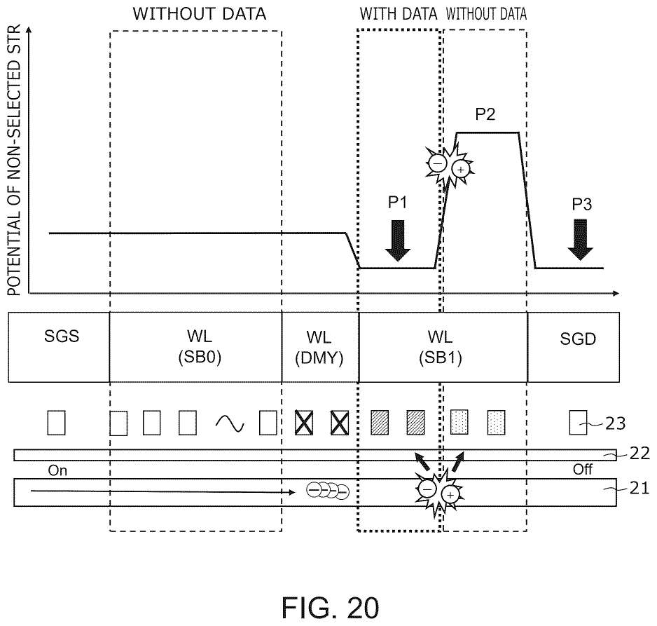

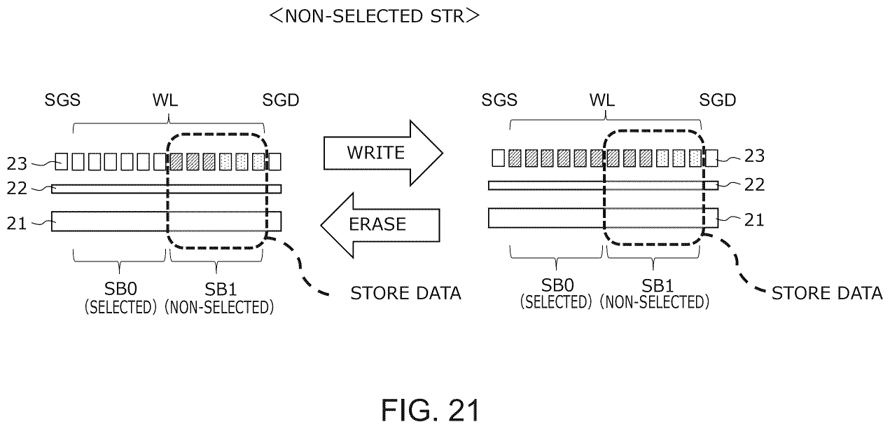

FIGS. 20 and 21 are diagrams for illustrating a problem of the erase verify operation of the second embodiment.

FIG. 20 illustrates a non-selected string in the range R2 in a case of performing an erase verify in an SBM. In FIG. 20, the sub-block SB0 is set as a selected sub-block, the sub-block SB1 is set as a non-selected sub-block, and the sub-block SB1 is in an open state. In FIG. 20, quadrangles marked with X indicate a plurality of dummy cells DMY, quadrangles with diagonal hatching indicate a plurality of written cells located to the right of the dummy cells DMY, and quadrangles with dotted hatching indicate a plurality of erased cells located to the right of the written cells. In FIG. 20, each memory cell MT in the sub-block SB0 is also an erased cell. FIG. 20 further illustrates a profile of a potential in the channel semiconductor layer 21 of the non-selected string.

In FIG. 20, the source-side select transistor ST is turned on, the drain-side select transistor DT is turned off, and electrons flow into the non-selected string from the source side. This causes the potential of the channel semiconductor layer 21 of the non-selected string to decrease. In FIG. 20, arrows P1, P2, and P3 indicate a potential at a position of the written cells in the sub-block SB1, a potential at a position of the erased cells in the sub-block SB1, and a potential at a position of the drain-side select transistor DT, respectively. Since the written cells are difficult to turn on, the potential P1 is a low potential. Since the erased cells are easy to turn on, the potential P2 is a high potential. Since the drain-side select transistor DT of the non-selected string is turned off in the erase verify, the potential P3 is a low potential.

In FIG. 20, a GIDL (Gate Induced Drain Leakage) current is generated at a boundary between the written cell and the erased cell in the sub-block SB1 due to a potential difference between the potential P1 and the potential P2. The GIDL current causes the write error. For example, when write and erase are repeated on the sub-block SB0 while the stored data in the sub-block SB1 is retained, a write error occurs due to hot carrier injection (HCI) (FIG. 21).

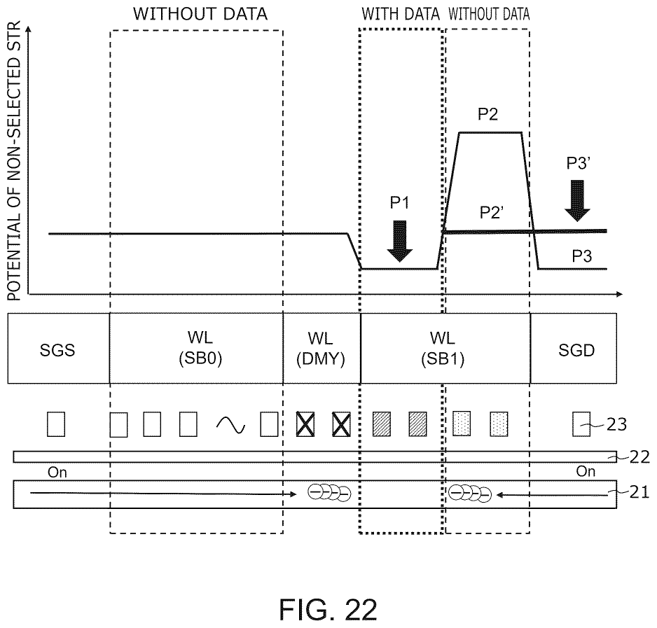

FIG. 22 is a diagram for illustrating an operation of a memory cell array 1 of the second embodiment.

FIG. 22 illustrates an example of an erase verify of the present embodiment, and specifically illustrates a non-selected string in the range R2 in a case of performing an erase verify in an SBM. In FIG. 22, the sub-block SB0 is set as a selected sub-block, the sub-block SB1 is set as a non-selected sub-block, and the sub-block SB1 is in an open state, as in FIG. 20. FIG. 22 further illustrates a profile of a potential in the channel semiconductor layer 21 of the non-selected string. The erase verify of the present embodiment is an example of a first erase verify.

In FIG. 22, the source-side select transistor ST and the drain-side select transistor DT are turned on, and electrons flow into the non-selected string from the source side and the drain side. This causes the potential of the channel semiconductor layer 21 of the non-selected string to decrease from the source side and the drain side. In FIG. 22, arrows P1, P2′, and P3′ indicate a potential at a position of the written cells in the sub-block SB1, a potential at a position of the erased cells in the sub-block SB1, and a potential at a position of the drain-side select transistor DT, respectively. In FIG. 22, since the drain-side select transistor DT is turned on, the potential P3′ is approximately an intermediate potential. Thus, the potential P2′ is also approximately an intermediate potential.

In the present embodiment, in the state illustrated in FIG. 22, the erase verify on the selected string is performed in a state where each of the dummy cells DMY, the source-side select transistor ST, and the drain-side select transistor DT in the non-selected string is turned on. This makes it possible to perform the erase verify while preventing the above-described write error. The present embodiment makes it possible to prevent the charges due to the GIDL current from causing the write error.

In the erase verify of the present embodiment, the drain-side select transistor DT in the non-selected string is temporarily turned on in the range R2 and the like, as illustrated in FIG. 22. This makes it possible to cause electrons to flow into the non-selected string from the source side and the drain side in the range R2 and the like. An example of a method of temporarily turning on the drain-side select transistor DT will be described later.

The erase verify illustrated in FIG. 22 may also be performed in a case where the non-selected string includes only written cells in the sub-block SB1, or in a case where the non-selected string includes only erased cells in the sub-block SB1. On the other hand, in the case where the non-selected string includes only written cells in the sub-block SB1, or in the case where the non-selected string includes only erased cells in the sub-block SB1, the erase verify illustrated in FIG. 20 may be performed instead of the erase verify illustrated in FIG. 22.

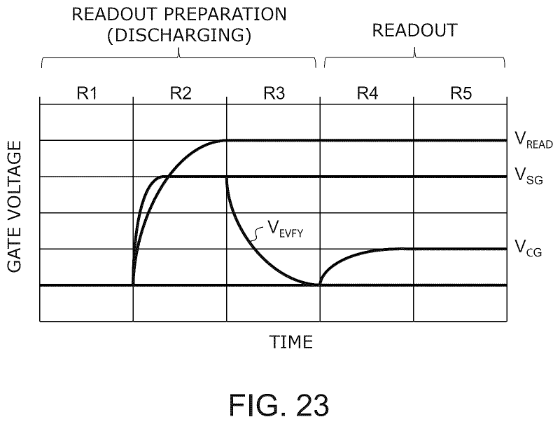

FIG. 23 is a graph for illustrating the operation of the memory cell array 1 of the second embodiment.

FIG. 23 illustrates a change in various gate voltages with time as in FIG. 17. The erase verify of the present embodiment is performed using gate voltages illustrated in FIG. 23, for example. In the present embodiment, the voltage applied to the gate of the drain-side select transistor DT in the non-selected string is not the voltage V_{SS} but a voltage V_{EVFY}, as illustrated in FIG. 23. The voltage V_{EVFY} rises in the range R2 from the value in the range R1, and drops in the range R3 to the value in the range R1. This makes it possible to temporarily turn on the drain-side select transistor DT.

### (1) First Modification of Second Embodiment

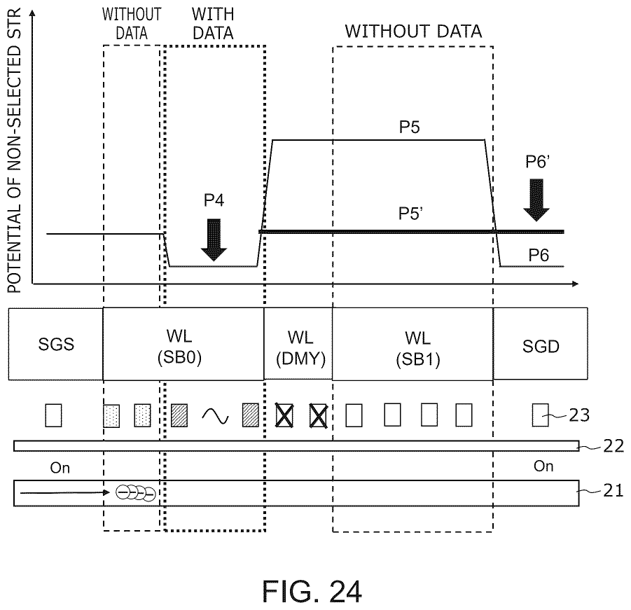

FIG. 24 is a diagram for illustrating an operation of the memory cell array 1 of a first modification of the second embodiment.

FIG. 24 illustrates an example of an erase verify of the present modification, and specifically illustrates a non-selected string in the range R2 in a case of performing an erase verify in an SBM. In FIG. 24, the sub-block SB1 is set as a selected sub-block, the sub-block SB0 is set as a non-selected sub-block, and the sub-block SB0 is in an open state. In FIG. 24, quadrangles marked with X indicate a plurality of dummy cells DMY, quadrangles with diagonal hatching indicate a plurality of written cells located to the left of the dummy cells DMY, and quadrangles with dotted hatching indicate a plurality of erased cells located to the left of the written cells. In FIG. 24, each memory cell MT in the sub-block SB1 is also an erased cell. FIG. 24 further illustrates a profile of a potential in the channel semiconductor layer 21 of the non-selected string. The erase verify of the present modification is an example of a second erase verify.

In FIG. 24, the source-side select transistor ST and the drain-side select transistor DT are turned on, and electrons can flow into the non-selected string from the source side and the drain side. This causes the potential of the channel semiconductor layer 21 of the non-selected string to decrease from the source side and the drain side. In FIG. 24, arrows P4, P5′, and P6′ indicate a potential at a position of the written cells in the sub-block SB0, a potential at a position of the erased cells in the sub-block SB1, and a potential at a position of the drain-side select transistor DT, respectively, in the present modification. In FIG. 24, since the drain-side select transistor DT is turned on, the potential P6′ is approximately an intermediate potential. Thus, the potential P5′ is also approximately an intermediate potential.

For comparison, FIG. 24 also illustrates potentials P5 and P6 when the source-side select transistor ST is turned on and the drain-side select transistor DT is turned off. The potential P5 indicates a potential at the position of the erased cell in the sub-block SB1, and the potential P6 indicates a potential at a position of the drain-side select transistor DT. In the present modification, the potential P5′ drops from the potential P5, and the potential P6′ rises from the potential P6.

In the present modification, in the state illustrated in FIG. 24, the erase verify on the selected string is performed in a state where each of the dummy cells DMY, the source-side select transistor ST, and the drain-side select transistor DT in the non-selected string is turned on. This makes it possible to perform the erase verify while preventing the above-described write error. The present modification makes it possible to prevent the charges due to the GIDL current from causing the write error.

In the erase verify of the present modification, the drain-side select transistor DT in the non-selected string is temporarily turned on in the range R2 and the like, as illustrated in FIG. 24. This makes it possible to cause electrons to flow into the non-selected string from the source side and the drain side in the range R2 and the like. In the present modification, as illustrated in FIG. 23, the voltage V_{SS} is replaced with the voltage V_{EVFY}, and thus the drain-side select transistor DT can be temporarily turned on.

The erase verify illustrated in FIG. 24 may also be performed in a case where the non-selected string includes only written cells in the sub-block SB0, or in a case where the non-selected string includes only erased cells in the sub-block SB0. On the other hand, in the case where the non-selected string includes only written cells in the sub-block SB0 or in the case where the non-selected string includes only erased cells in the sub-block SB0, an erase verify different from the erase verify illustrated in FIG. 24 may be performed.

In FIGS. 15A to 15C, the same voltage V_{SG} is applied to the gates of the four source-side select transistors ST in one block BLK. Such control can be implemented by short-circuiting the four source-side select lines SGS for these source-side select transistors ST to each other. In the erase verify of the present modification, since the voltage V_{SG} is set such that the source-side select transistor ST and the drain-side select transistor DT in the selected string are kept in the on state, the source-side select transistor ST in the non-selected string is also kept in an on state due to the short circuit. Furthermore, these source-side select lines SGS do not have to be short-circuited to each other. Even when these source-side select lines SGS are not short-circuited to each other, the erase verify of the present modification can be implemented.

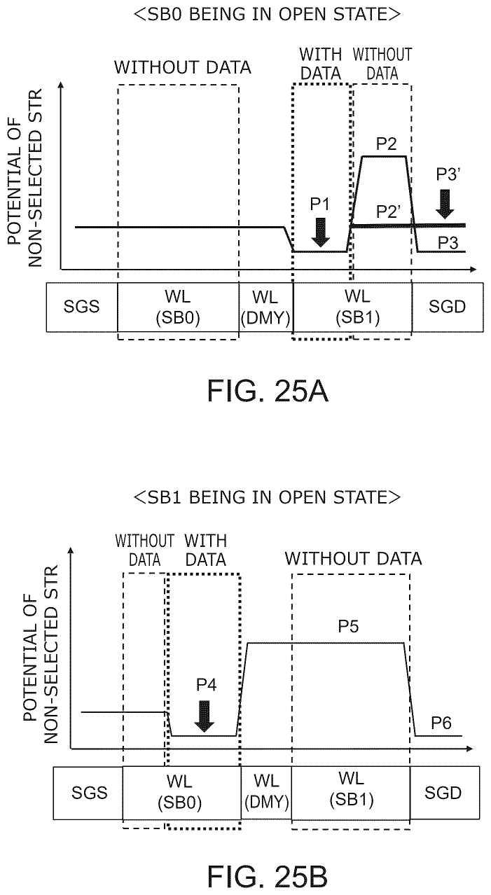

In the present embodiment, the erase verify in FIG. 22 may be performed when the sub-block SB0 is the selected sub-block, and the erase verify in FIG. 24 may be performed when the sub-block SB1 is the selected sub-block. Alternatively, the erase verify in FIG. 22 may be performed when the sub-block SB0 is the selected sub-block, and an erase verify in FIGS. 25A and 25B to be described below may be performed when the sub-block SB1 is the selected sub-block.

### (2) Second Modification of Second Embodiment

FIGS. 25A and 25B are diagrams for illustrating an operation of the memory cell array 1 of a second modification of the second embodiment.

FIG. 25A illustrates an example of an erase verify of the present modification, and specifically illustrates a potential profile of a non-selected string in the range R2 in a case of performing an erase verify in an SBM. In FIG. 25A, the sub-block SB0 is set as a selected sub-block, the sub-block SB1 is set as a non-selected sub-block, and the sub-block SB1 is in an open state, as in FIG. 22.

The erase verify in FIG. 25A is performed in the same manner as the erase verify in FIG. 22. Therefore, the source-side select transistor ST is turned on, the drain-side select transistor DT is also turned on, and potentials in the channel semiconductor layer 21 of the non-selected string are set as indicated by arrows P1, P2′, and P3′. The erase verify in FIG. 25A is an example of a first erase verify.

FIG. 25B illustrates another example of an erase verify of the present modification, and specifically illustrates a potential profile of a non-selected string in the range R2 in a case of performing an erase verify in an SBM. In FIG. 25B, the sub-block SB1 is set as a selected sub-block, the sub-block SB0 is set as a non-selected sub-block, and the sub-block SB0 is in an open state, as in FIG. 24.

The erase verify in FIG. 25B is performed in a manner different from that of the erase verify in FIG. 24. In FIG. 25B, the source-side select transistor ST is turned on, the drain-side select transistor DT is turned off, and potentials in the channel semiconductor layer 21 of the non-selected string are set as indicated by arrows P4, P5, and P6. The erase verify in FIG. 25B is an example of a second erase verify.

In FIG. 25B, since source-side select transistor ST is turned on, a potential difference at a boundary between the written cell and the erased cell in the sub-block SB0 is small. For this reason, a write error due to the boundary is unlikely to occur. Therefore, it is useless to turn on the drain-side select transistor DT. The present embodiment makes it possible to avoid the drain-side select transistor DT from being turned on uselessly by turning off the drain-side select transistor DT in FIG. 25B, thereby making it possible to save power consumption of the memory system.

The erase verify illustrated in FIG. 25B may also be performed in a case where the non-selected string includes only written cells in the sub-block SB0, or in a case where the non-selected string includes only erased cells in the sub-block SB0. On the other hand, in the case where the non-selected string includes only written cells in the sub-block SB0, or in the case where the non-selected string includes only erased cells in the sub-block SB0, an erase verify different from the erase verify illustrated in FIG. 25B may be performed.

### (3) Third Modification of Second Embodiment

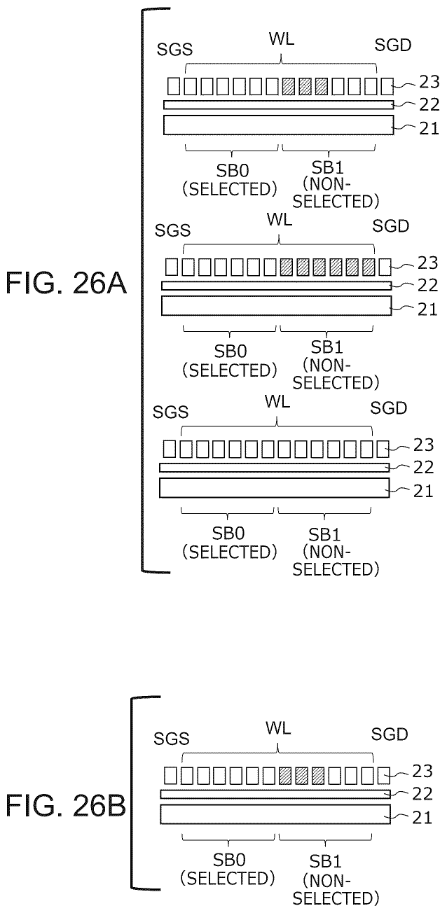

FIGS. 26A and 26B are diagrams for illustrating an operation of the memory cell array 1 of a third modification of the second embodiment.

FIG. 26A illustrates a first example of an erase verify of the present modification, and specifically illustrates a non-selected string in a case of performing an erase verify in an SBM. In FIG. 26A, quadrangles with diagonal hatching indicate a plurality of written cells, and quadrangle without hatching indicate a plurality of erased cells.

In an upper diagram in FIG. 26A, the non-selected string includes written cells and erased cells in the sub-block SB1. In a middle diagram in FIG. 26A, the non-selected string includes only written cells in the sub-block SB1. In a lower diagram in FIG. 26A, the non-selected string includes only erased cells in the sub-block SB1. In these diagrams, the sub-block SB0 is set as a selected sub-block, and the sub-block SB1 is set as a non-selected sub-block.

The erase verify in FIG. 26A is performed in the same manner as the erase verify in FIG. 22. Therefore, in the range R2 of the erase verify in FIG. 26A, the source-side select transistor ST is turned on, and the drain-side select transistor DT is also turned on. The erase verify illustrated in FIG. 26A is performed in a case where the non-selected string includes the written cells and the erased cells in the sub-block SB1, in a case where the non-selected string includes only the written cells in the sub-block SB1, and in a case where the non-selected string includes only the erased cells in the sub-block SB1.

FIG. 26B illustrates a second example of an erase verify of the present modification, and specifically illustrates a non-selected string in a case of performing an erase verify in an SBM. In FIG. 26B, the non-selected string includes written cells and erased cells in the sub-block SB1. In FIG. 26B, the sub-block SB0 is set as a selected sub-block, and the sub-block SB1 is set as a non-selected sub-block.

The erase verify in FIG. 26B is also performed in the same manner as the erase verify in FIG. 22. Therefore, in the range R2 of the erase verify in FIG. 26B, the source-side select transistor ST is turned on, and the drain-side select transistor DT is also turned on. The erase verify illustrated in FIG. 26B is performed in a case where the non-selected string includes the written cells and the erased cells in the sub-block SB1. On the other hand, the erase verify illustrated in FIG. 26B is performed in the same manner as the erase verify in FIG. 20 in a case where the non-selected string includes only the written cells in the sub-block SB1 and in a case where the non-selected string includes only the erased cells in the sub-block SB1.

In the memory system in FIG. 1, the memory controller 102 manages information indicating whether each of the memory cells MT in the memory cell array 1 is a written cell or an erased cell. In the erase verify in FIG. 26B, the NAND memory 101 receives this information from the memory controller 102, and performs the erase verify in FIG. 26B based on the received information. For example, when the information indicates that a certain non-selected string includes the written cells and the erased cells in the sub-block SB1, the process in FIG. 22 is performed on the non-selected string. On the other hand, when the information indicates that a certain non-selected string includes only the written cells or only the erased cells in the sub-block SB1, the process in FIG. 20 is performed on the non-selected string. Such an operation of the NAND memory 101 is controlled by the control circuit 11, for example.

On the other hand, the erase verify in FIG. 26A may be performed when the above-described information is notified from the memory controller 102 to the NAND memory 101, or may be performed when the information is not notified from the memory controller 102 to the NAND memory 101. In the erase verify in FIG. 26A, since the process in FIG. 22 is performed in either case, the NAND memory 101 can perform the erase verify in FIG. 26A without using the above-described information. In other words, when performing the erase verify in FIG. 26A, the NAND memory 101 may perform the erase verify after grasping the state of each of the memory cells MT in the sub-block SB1, or may perform the erase verify without grasping the state of each of the memory cells MT in the sub-block SB1.

In addition, the present modification can be also applied to the case where the sub-block SB1 is set as the selected sub-block and the sub-block SB0 is set as the non-selected sub-block.

As described above, in the erase verify of the selected string in the present embodiment, for example, the drain-side select transistor DT in the non-selected string is temporarily turned on, as illustrated in FIG. 22 and the like. Therefore, the present embodiment makes it possible to appropriately perform the erase verify in the SBM, and thus, to appropriately perform the erase operation in the SBM.

In the SBM of the present embodiment, each of the blocks BLK may be divided into three or more sub-blocks. In this case, the control of the write operation and the precharge described with reference to FIG. 14B may be similarly applied to the control of the erase operation and the erase verify of the present embodiment.

While certain embodiments have been described, these embodiments have been presented by way of example only, and are not intended to limit the scope of the inventions. Indeed, the novel devices described herein may be embodied in a variety of other forms; furthermore, various omissions, substitutions and changes in the form of the devices described herein may be made without departing from the spirit of the inventions. The accompanying claims and their equivalents are intended to cover such forms or modifications as would fall within the scope and spirit of the inventions.

1. A semiconductor storage device comprising:
a first string including a plurality of memory cells, a first select transistor, and a second select transistor,
wherein the plurality of memory cells in the first string include:
a plurality of first memory cells in a first sub-block adjacent to the first select transistor;
a plurality of second memory cells in a second sub-block adjacent to the second select transistor; and
a first intermediate cell between the first sub-block and the second sub-block, and
when a write operation is performed in which the first sub-block is set as a selected sub-block, the second sub-block is set as a non-selected sub-block, the first string is set as a non-selected string, and a second string different from the first string is set as a selected string, a first precharge on the first string is performed in a state where the first intermediate cell is turned off, the first select transistor is turned on, and the second select transistor is turned on.

2. The device of claim 1, wherein the first precharge is performed when the plurality of second memory cells include a written cell and an erased cell.

3. The device of claim 1, wherein the first precharge is performed when the plurality of second memory cells include an erased cell and include no written cell.

4. The device of claim 1, wherein the first precharge is performed when the plurality of second memory cells include a written cell and include no erased cell.

5. The device of claim 1, wherein when the write operation is performed, a second precharge on the first string is performed in a state where the first intermediate cell is turned off, the first select transistor is turned on, and the second select transistor is turned off.

6. The device of claim 5, wherein
the second precharge is performed when the plurality of second memory cells include a written cell and include no erased cell, and
the first precharge is performed when the plurality of second memory cells include an erased cell.

7. The device of claim 1, wherein
the plurality of memory cells in the first string include:
the plurality of first memory cells in the first sub-block;
the plurality of second memory cells in the second sub-block;
a plurality of third memory cells in a third sub-block located between the first sub-block and the second sub-block;
the first intermediate cell between the first sub-block and the third sub-block; and
a second intermediate cell between the second sub-block and the third sub-block.

8. The device of claim 7, wherein when a write operation is performed in which the first and second sub-blocks are set as non-selected sub-blocks, the third sub-block is set as a selected sub-block, the first string is set as a non-selected string, and the second string is set as a selected string, a third precharge on the first string is performed in a state where one of the first and second intermediate cells is turned off, the other of the first and second intermediate cells is turned on, the first select transistor is turned on, and the second select transistor is turned on.

9. The device of claim 1, wherein the device is configured to receive information relating to a written cell and an erased cell in the first string from a memory controller, and perform the first precharge based on the received information.

10. The device of claim 1, further comprising a control circuit configured to control the first precharge.

11. A semiconductor storage device comprising:
a first string including a plurality of memory cells, a first select transistor on a source side, and a second select transistor on a drain side,
wherein the plurality of memory cells in the first string include:
a plurality of first memory cells in a first sub-block adjacent to the first select transistor; and
a plurality of second memory cells in a second sub-block adjacent to the second select transistor, and
when a first erase verify is performed in which the first sub-block is set as a selected sub-block, the second sub-block is set as a non-selected sub-block, the first string is set as a non-selected string, and a second string different from the first string is set as a selected string, the first erase verify is performed in a state where the second select transistor is turned on.

12. The device of claim 11, wherein the first erase verify is performed in a state where the first select transistor is turned on and the second select transistor is turned on.

13. The device of claim 11, wherein the first erase verify is performed when the plurality of second memory cells include a written cell and an erased cell.

14. The device of claim 11, wherein when a second erase verify is performed in which the first sub-block is set as a non-selected sub-block, the second sub-block is set as a selected sub-block, the first string is set as a non-selected string, and the second string is set as a selected string, the second erase verify is performed in a state where the first select transistor is turned on and the second select transistor is turned on.

15. The device of claim 14, wherein the second erase verify is performed when the plurality of first memory cells include a written cell and an erased cell.

16. The device of claim 11, wherein when a second erase verify is performed in which the first sub-block is set as a non-selected sub-block, the second sub-block is set as a selected sub-block, the first string is set as a non-selected string, and the second string is set as a selected string, the second erase verify is performed in a state where the first select transistor is turned on and the second select transistor is turned off.

17. The device of claim 16, wherein the second erase verify is performed when the plurality of first memory cells include a written cell and an erased cell.

18. The device of claim 11, wherein a select line for the first select transistor in the first string is short-circuited with a select line for the first select transistor in the second string.

19. The device of claim 11, wherein the device is configured to receive information relating to a written cell and an erased cell in the first string from a memory controller, and perform the first erase verify based on the received information.

20. The device of claim 11, further comprising a control circuit configured to control the first erase verify.
